(19) United States
(12) Patent Application Publication
(10) Pub. No.: US 2025/0021861 A1
(43) Pub. Date: Jan. 16, 2025

(54) DIGITAL TWIN FOR AI/ML TRAINING AND TESTING

(71) Applicants: Rakuten Symphony UK Ltd, Surrey (GB); RAKUTEN MOBILE USA LLC, San Mateo, CA (US)

(72) Inventors: Kexuan SUN, Surrey (GB); Antonio FORENZA, San Mateo, CA (US)

(73) Assignees: Rakuten Symphony UK Ltd, Surrey (GB); RAKUTEN MOBILE USA LLC, San Mateo, CA (US)

(21) Appl. No.: 18/005,112

(22) PCT Filed: Nov. 10, 2022
(86) PCT No.: PCT/US2022/049480

§ 371 Date: Jan. 11, 2023

(51) Int. Cl. G06N 20/00; G06F 30/20

(52) U.S. Cl. CPC G06N 20/00; G06F 30/20

(57) ABSTRACT

A method of simulating a network for machine learning and training is provided. The method can include generating a simulated model (digital twin) of a network, wherein the simulated model is based on receiving network data from the network. The method can also include training a machine learning model based on data received from the simulated model and operating the trained machine learning model within the network. In addition, the network may be based on an open radio access network (O-RAN). Further, the method may include operating the simulated model within a non-real-time (Non-RT) radio access network intelligent controller (RIC) framework. Also, the method may include operating the simulated model within a near-real-time (Near-RT) radio access network intelligent controller (RIC) framework. In addition, the method may include operating the simulated model in parallel with the O-RAN.

### BACKGROUND

### Technical Field

The present disclosure described herein relates to simulating an open radio access network (O-RAN) for machine learning and training.

### Background

Artificial intelligence (AI) and machine learning (ML) based technology for radio access network (RAN) automation, management, orchestration, and optimization represents a key factor for the foundations of the open radio access network (O-RAN) architecture. In particular, non-real-time (RT) and near-RT RAN intelligent controllers (RIC) are currently the two main hosts that enable RAN intelligence. However, there are many problems and challenges with conventional systems which need to be addressed in the entire RAN industry before any AI/ML-powered solutions can be commercially deployed and create real business values.

In particular, data availability for AI/ML model training is one of the main challenges faced by the industry. Conventional AI/ML models are normally trained with real network data captured through either vendor preparatory or standardized key performance indicator (KPI) exposed interfaces which present the following challenges, namely: Limited data access, limited real-world sunny-day and rainy-day scenarios, and limited dynamic interaction between AI/ML models and the network.

Further, testing for rApps/xApps (which can be automation tools and applications) hosted by the Non-RT or Near-RT RIC or any application running on any virtual RAN platform is challenging when performed over a live network because of the negative impact it may cause to the performance of the network itself. For example, any application implementing automatic antenna titling methods to reduce inter-cell interference or increase cell coverage may cause significant performance degradation over the live network if the parameters, configurations, or logic of those methods are not extensively tested over a simulation platform and if that simulation platform is not a close enough representative of the real-world network.

### SUMMARY

According to example embodiments, the disclosure described herein provides a novel architecture for introducing a “digital twin” module in the AI/ML training host of Non-RT RIC. Here, the digital twin, implemented through digital simulation and modelling, can represent a digital replica of a physical O-RAN network connected with the RIC. The AI/ML model before deployment in the rAppls/xApps can be trained with a training data set generated from the digital twin which can complement the limitation of real data captured from the physical network. The digital twin module can be calibrated with the physical network data in order to create an accurate replica of the network for not only the historical state when the physical network data was captured but also any future or unseen states for generating and constructing training scenarios. According to one or more example embodiments, the digital twin module can be deployed in Near-RT RIC, rApp, xApps, or external to RIC supporting both offline and online training of AI/ML models.

In other example embodiments, one of the many applications of the disclosure described herein is to create a light-weight digital replica (or a virtual environment, model, or simulation) of the physical O-RAN network that is as realistic as the real physical environment for efficient AI/ML model training and testing. This can be provided via advanced wireless network modelling and data driven model calibration technologies. For example, billions of training and testing scenarios can be generated automatically from the digital twin module of the disclosure described herein which can significantly improve the performances and reliability of AI/ML solutions in the RIC, while greatly reducing the cost and overcoming data availability challenges, among other advantages or technical improvements. Here, the method and system of the disclosure described herein can help to accelerate the maturity and commercial deployment of O-RAN technologies and RAN Intelligence technologies. Further, the methods and systems of the disclosure described herein can also be applied and bring significant value to any other types of wireless network with intelligence, including but not limited to 4G, 5G and 6G network not based on O-RAN standard, and WiFi, BlueTooth, LoRa, V2X and D2D.

In other example embodiments, a method of creating a lightweight and realistic digital replica of a network for machine learning and training, the method including generating a digital twin of a network, wherein the digital twin is calibrated based on receiving performance metrics data from the network; training a machine learning model based on data generated from the digital twin; and operating the trained machine learning model within the network.

In addition, the method may include wherein the network is based on an open radio access network (O-RAN).

Further, the method may include operating the digital twin within a non-real-time (Non-RT) radio access network intelligent controller (RIC) framework as part of an artificial intelligence (AI) or machine learning (ML) workflow for AI or ML model training and testing.

Also, the method may include operating the digital twin within a near-real-time (Near-RT) radio access network intelligent controller (RIC) framework as part of an artificial intelligence (AI) or machine learning (ML) workflow for AI or ML model training and testing.

Moreover, the method may include operating the digital twin in parallel with the O-RAN, wherein the digital twin is further operated outside of a non-real-time (Non-RT) radio access network intelligent controller (RIC) framework and a near-real-time (Near-RT) radio access network intelligent controller (RIC) framework.

In addition, the method may include the step of generating a digital twin of the network further comprises:

Also, the method may include analyzing a performance of the machine learning model; and generating one or more network scenarios via radio access network (RAN) scenario generator based on the performance of the machine learning model.

Further, the method may include modeling the network based on the received network data from the network and the generated one or more network scenarios from the RAN scenario generator.

In addition, the method may include monitoring a performance of the modeled network; providing feedback to the RAN scenario generator based on the monitored performance of the modeled network; and

Also, the method may include optimizing the modeled network based on the provided feedback to the RAN scenario generator.

Moreover, the method may include wherein the digital twin comprises an offline simulation module and a runtime simulation module.

Further, the method may include generating user equipment (UE) mobility pattern within the offline simulation module; simulating radio frequency (RF) propagation within the offline simulation module, and generating an RF map at least partially representing power and interference at each location within a geographical area; and loading the UE mobility pattern and RF map generated to generate training or testing data to an artificial intelligence (AI) or machine learning (ML) model under training or testing in run time.

In other example embodiments, an apparatus for creating a lightweight and realistic digital replica of a network for machine learning and training, including a memory storage storing computer-executable instructions; and a processor communicatively coupled to the memory storage, wherein the processor is configured to execute the computer-executable instructions and cause the apparatus to: generate a digital twin of a network, wherein the digital twin is calibrated based on receiving performance metrics data from the network; train a machine learning model based on data generated from the digital twin; and operate the trained machine learning model within the network.

In addition, the apparatus may include wherein the network is based on an open radio access network (O-RAN).

Further, the computer-executable instructions, when executed by the processor, may further cause the apparatus to operate the digital twin within a non-real-time (Non-RT) radio access network intelligent controller (RIC) framework as part of an artificial intelligence (AI) or machine learning (ML) workflow for AI or ML model training and testing.

Moreover, the computer-executable instructions, when executed by the processor, may further cause the apparatus to operate the digital twin within a near-real-time (Near-RT) radio access network intelligent controller (RIC) framework as part of an artificial intelligence (AI) or machine learning (ML) workflow for AI or ML model training and testing.

Also, the computer-executable instructions, when executed by the processor, further cause the apparatus to operate the digital twin in parallel with the O-RAN, wherein the digital twin is further operated outside of a non-real-time (Non-RT) radio access network intelligent controller (RIC) framework and a near-real-time (Near-RT) radio access network intelligent controller (RIC) framework.

In addition, the step of generating a digital twin of the network, wherein the computer-executable instructions, when executed by the processor, may further cause the apparatus to analyze a performance of the machine learning model; and generate one or more network scenarios via radio access network (RAN) scenario generator based on the performance of the machine learning model.

Also, the computer-executable instructions, when executed by the processor, may further cause the apparatus to model the network based on the received network data from the network and the generated one or more network scenarios from the RAN scenario generator.

Further, the computer-executable instructions, when executed by the processor, may further cause the apparatus to monitor a performance of the modeled network; provide feedback to the RAN scenario generator based on the monitored performance of the modeled network; and optimize the modeled network based on the provided feedback to the RAN scenario generator.

Moreover, the digital twin may include an offline simulation module and a runtime simulation module.

In other example embodiments, a non-transitory computer-readable medium comprising computer-executable instructions for creating a lightweight and realistic digital replica of a a network for machine learning and training by an apparatus, wherein the computer-executable instructions, when executed by at least one processor of the apparatus, cause the apparatus to generate a digital twin of a network, wherein the digital twin is calibrated based on receiving performance metrics data from the network; train a machine learning model based on data generated from the digital twin; and operate the trained machine learning model within the network.

### BRIEF DESCRIPTION OF THE DRAWINGS

Features, advantages, and significance of exemplary embodiments of the disclosure will be described below with reference to the accompanying drawings, in which like signs denote like elements, and wherein:

FIG. 1 illustrates a diagram of a general system architecture of the network simulation and machine learning method and system of the disclosure described herein according to one or more embodiments;

FIG. 2 illustrates a diagram of a process flow and various modules for the network simulation and machine learning method and system of the disclosure described herein according to one or more embodiments;

FIG. 3 illustrates another diagram of a process flow and various modules for the network simulation and machine learning method and system of the disclosure described herein according to one or more embodiments;

FIG. 4 illustrates another diagram of a process flow and various modules for the network simulation and machine learning platform method and system of the disclosure described herein according to one or more embodiments;

FIG. 5 illustrates another diagram of a process flow and various modules for the network simulation and machine learning method and system of the disclosure described herein according to one or more embodiments;

FIG. 6 illustrates another diagram of a process flow and various modules for the network simulation and machine learning method and system of the disclosure described herein according to one or more embodiments;

FIG. 7 illustrates another diagram of a process flow and various modules for the network simulation and machine learning method and system of the disclosure described herein according to one or more embodiments;

FIG. 8 illustrates another diagram of a process flow and various modules for the network simulation and machine learning method and system of the disclosure described herein according to one or more embodiments; and

FIG. 9 illustrates another diagram of a process flow and various units/modules for the network simulation and machine learning method and system of the disclosure described herein according to one or more embodiments.

### DETAILED DESCRIPTION

The following detailed description of example embodiments refers to the accompanying drawings. The same reference numbers in different drawings may identify the same or similar elements.

The foregoing disclosure provides illustrations and descriptions, but is not intended to be exhaustive or to limit the implementations to the precise form disclosed. Modifications and variations are possible in light of the above disclosure or may be acquired from practice of the implementations. Further, one or more features or components of one embodiment may be incorporated into or combined with another embodiment (or one or more features of another embodiment). Additionally, in the flowcharts and descriptions of operations provided below, it is understood that one or more operations may be omitted, one or more operations may be added, one or more operations may be performed simultaneously (at least in part), and the order of one or more operations may be switched.

It will be apparent that systems and/or methods, described herein, may be implemented in different forms of hardware, firmware, or a combination of hardware and software. The actual specialized control hardware or software code used to implement these systems and/or methods is not limiting of the implementations. Thus, the operation and behavior of the systems and/or methods were described herein without reference to specific software code—it being understood that software and hardware may be designed to implement the systems and/or methods based on the description herein.

Even though particular combinations of features are recited in the claims and/or disclosed in the specification, these combinations are not intended to limit the disclosure of possible implementations. In fact, many of these features may be combined in ways not specifically recited in the claims and/or disclosed in the specification. Although each dependent claim listed below may directly depend on only one claim, the disclosure of possible implementations includes each dependent claim in combination with every other claim in the claim set.

No element, act, or instruction used herein should be construed as critical or essential unless explicitly described as such. Also, as used herein, the articles “a” and “an” are intended to include one or more items, and may be used interchangeably with “one or more.” Where only one item is intended, the term “one” or similar language is used. Also, as used herein, the terms “has,” “have,” “having,” “include,” “including,” or the like are intended to be open-ended terms. Further, the phrase “based on” is intended to mean “based, at least in part, on” unless explicitly stated otherwise. Furthermore, expressions such as “at least one of [A] and [B]” or “at least one of [A] or [B]” are to be understood as including only A, only B, or both A and B.

Reference throughout this specification to “one embodiment,” “an embodiment,” “non-limiting exemplary embodiment,” or similar language means that a particular feature, structure, or characteristic described in connection with the indicated embodiment is included in at least one embodiment of the present solution. Thus, the phrases “in one embodiment”, “in an embodiment,” “in one non-limiting exemplary embodiment,” and similar language throughout this specification may, but do not necessarily, all refer to the same embodiment.

Furthermore, the described features, advantages, and characteristics of the present disclosure may be combined in any suitable manner in one or more embodiments. One skilled in the relevant art will recognize, in light of the description herein, that the present disclosure can be practiced without one or more of the specific features or advantages of a particular embodiment. In other instances, additional features and advantages may be recognized in certain embodiments that may not be present in all embodiments of the present disclosure.

In one implementation of the disclosure described herein, a display page may include information residing in the computing device's memory, which may be transmitted from the computing device over a network to a database center and vice versa. The information may be stored in memory at each of the computing device, a data storage resided at the edge of the network, or on the servers at the database centers. A computing device or mobile device may receive non-transitory computer readable media, which may contain instructions, logic, data, or code that may be stored in persistent or temporary memory of the mobile device, or may somehow affect or initiate action by a mobile device. Similarly, one or more servers may communicate with one or more mobile devices across a network, and may transmit computer files residing in memory. The network, for example, can include the Internet, wireless communication network, or any other network for connecting one or more mobile devices to one or more servers.

Any discussion of a computing or mobile device may also apply to any type of networked device, including but not limited to mobile devices and phones such as cellular phones (e.g., any “smart phone”), a personal computer, server computer, or laptop computer; personal digital assistants (PDAs); a roaming device, such as a network-connected roaming device; a wireless device such as a wireless email device or other device capable of communicating wireless with a computer network; or any other type of network device that may communicate over a network and handle electronic transactions. Any discussion of any mobile device mentioned may also apply to other devices, such as devices including short-range ultra-high frequency (UHF) device, near-field communication (NFC), infrared (IR), and Wi-Fi functionality, among others.

Phrases and terms similar to “software”, “application”, “app”, and “firmware” may include any non-transitory computer readable medium storing thereon a program, which when executed by a computer, causes the computer to perform a method, function, or control operation.

Phrases and terms similar to “network” may include one or more data links that enable the transport of electronic data between computer systems and/or modules. When information is transferred or provided over a network or another communications connection (either hardwired, wireless, or a combination of hardwired or wireless) to a computer, the computer uses that connection as a computer-readable medium. Thus, by way of example, and not limitation, computer-readable media can also include a network or data links which can be used to carry or store desired program code means in the form of computer-executable instructions or data structures and which can be accessed by a general purpose or special purpose computer.

Phrases and terms similar to “portal” or “terminal” may include an intranet page, internet page, locally residing software or application, mobile device graphical user interface, or digital presentation for a user. The portal may also be any graphical user interface for accessing various modules, components, features, options, and/or attributes of the disclosure described herein. For example, the portal can be a web page accessed with a web browser, mobile device application, or any application or software residing on a computing device.

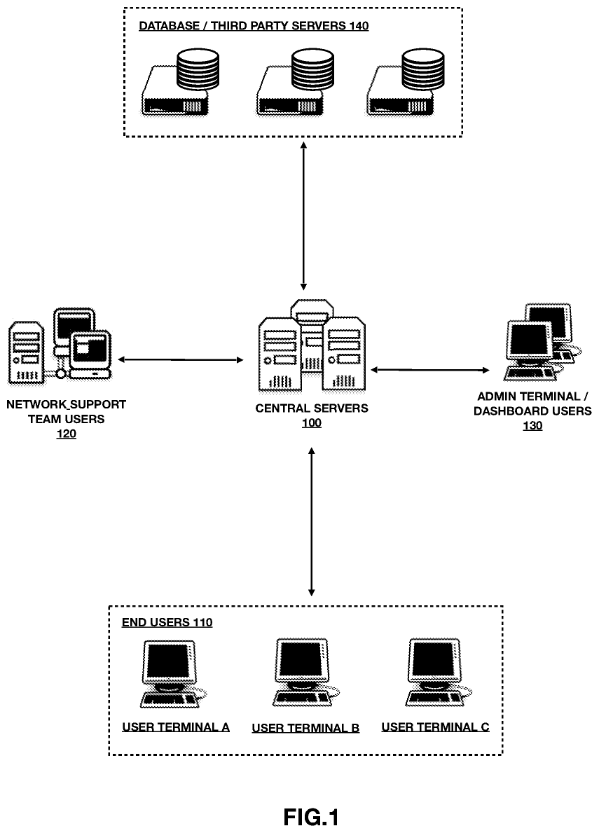

FIG. 1 illustrates a diagram of a general network architecture according to one or more embodiments. Referring to FIG. 1, end users 110, network support team users 120, and admin terminal/dashboard users 130 (collectively referred to herein as users 110, 120, and 130) can be in bi-directional communication over a secure network with central servers or application servers 100 according to one or more embodiments. In addition, users 110, 120, 130 may also be in direct bi-directional communication with each other via the network system of the disclosure described herein according to one or more embodiments. Here, users 110 can be any type of customer, network service provider agent, or vendor, among others, of a network or telecommunication service provider, such as users operating computing devices and user terminals A, B, and C. Each of users 110 can communicate with servers 100 via their respective terminals or portals, wherein servers 110 can provide or automatically operate the network impact prediction engine system and method of the disclosure described herein. Users 120 can include application development members or support agents of the network service provider for developing, integrating, and monitoring the network simulation and machine learning method and system of the disclosure described herein, including assisting, scheduling/modifying network events, and providing support services to end users 110. Admin terminal/dashboard users 130 may be any type of user with access privileges for accessing a dashboard or management portal of the disclosure described herein, wherein the dashboard portal can provide various user tools, GUI information, maps, open/closed/pending support tickets, graphs, and customer support options. It is contemplated within the scope of the present disclosure described herein that any of users 110 and 120 may also access the admin terminal/dashboard 130 of the disclosure described herein.

Still referring to FIG. 1, central servers 100 of the disclosure described herein according to one or more embodiments can be in further bi-directional communication with database/third party servers 140, which may also include users. Here, servers 140 can include vendors and databases where various captured, collected, or aggregated data, such as current, real-time, and past network related historical and KPI data, may be stored thereon and retrieved therefrom for network analysis, RCA, artificial intelligence (AI) processing, neural network models, machine learning, predictions, and simulations by servers 100. In addition, servers 100 may include the digital twin module of the disclosure described herein. However, it is contemplated within the scope of the present disclosure described herein that the network simulation and machine learning method and system of the disclosure described herein can include any type of general network architecture.

Still referring to FIG. 1, one or more of servers or terminals of elements 100-140 may include a personal computer (PC), a printed circuit board comprising a computing device, a mini-computer, a mainframe computer, a microcomputer, a telephonic computing device, a wired/wireless computing device (e.g., a smartphone, a personal digital assistant (PDA)), a laptop, a tablet, a smart device, a wearable device, or any other similar functioning device.

In some embodiments, as shown in FIG. 1, one or more servers, terminals, and users 100-140 may include a set of components, such as a processor, a memory, a storage component, an input component, an output component, a communication interface, and a JSON UI rendering component. The set of components of the device may be communicatively coupled via a bus.

The bus may comprise one or more components that permit communication among the set of components of one or more of servers or terminals of elements 100-140. For example, the bus may be a communication bus, a cross-over bar, a network, or the like. The bus may be implemented using single or multiple (two or more) connections between the set of components of one or more of servers or terminals of elements 100-140. The disclosure is not limited in this regard.

One or more of servers or terminals of elements 100-140 may comprise one or more processors. The one or more processors may be implemented in hardware, firmware, and/or a combination of hardware and software. For example, the one or more processors may comprise a central processing unit (CPU), a graphics processing unit (GPU), an accelerated processing unit (APU), a microprocessor, a microcontroller, a digital signal processor (DSP), a field-programmable gate array (FPGA), an application-specific integrated circuit (ASIC), a general purpose single-chip or multi-chip processor, or other programmable logic device, discrete gate or transistor logic, discrete hardware components, or any combination thereof designed to perform the functions described herein. A general purpose processor may be a microprocessor, or any conventional processor, controller, microcontroller, or state machine. The one or more processors also may be implemented as a combination of computing devices, such as a combination of a DSP and a microprocessor, a plurality of microprocessors, one or more microprocessors in conjunction with a DSP core, or any other such configuration. In some embodiments, particular processes and methods may be performed by circuitry that is specific to a given function.

The one or more processors may control overall operation of one or more of servers or terminals of elements 100-140 and/or of the set of components of one or more of servers or terminals of elements 100-140 (e.g., memory, storage component, input component, output component, communication interface, rendering component).

One or more of servers or terminals of elements 100-140 may further comprise memory. In some embodiments, the memory may comprise a random access memory (RAM), a read only memory (ROM), an electrically erasable programmable ROM (EEPROM), a flash memory, a magnetic memory, an optical memory, and/or another type of dynamic or static storage device. The memory may store information and/or instructions for use (e.g., execution) by the processor.

A storage component of one or more of servers or terminals of elements 100-140 may store information and/or computer-readable instructions and/or code related to the operation and use of one or more of servers or terminals of elements 100-140. For example, the storage component may include a hard disk (e.g., a magnetic disk, an optical disk, a magneto-optic disk, and/or a solid state disk), a compact disc (CD), a digital versatile disc (DVD), a universal serial bus (USB) flash drive, a Personal Computer Memory Card International Association (PCMCIA) card, a floppy disk, a cartridge, a magnetic tape, and/or another type of non-transitory computer-readable medium, along with a corresponding drive.

One or more of servers or terminals of elements 100-140 may further comprise an input component. The input component may include one or more components that permit one or more of servers and terminals 100-140 to receive information, such as via user input (e.g., a touch screen, a keyboard, a keypad, a mouse, a stylus, a button, a switch, a microphone, a camera, and the like). Alternatively or additionally, the input component may include a sensor for sensing information (e.g., a global positioning system (GPS) component, an accelerometer, a gyroscope, an actuator, and the like).

An output component any one or more of servers or terminals of elements 100-140 may include one or more components that may provide output information from the device 100 (e.g., a display, a liquid crystal display (LCD), light-emitting diodes (LEDs), organic light emitting diodes (OLEDs), a haptic feedback device, a speaker, and the like).

One or more of servers or terminals of elements 100-140 may further comprise a communication interface. The communication interface may include a receiver component, a transmitter component, and/or a transceiver component. The communication interface may enable one or more of servers or terminals of elements 100-140 to establish connections and/or transfer communications with other devices (e.g., a server, another device). The communications may be enabled via a wired connection, a wireless connection, or a combination of wired and wireless connections. The communication interface may permit one or more of servers or terminals of elements 100-140 to receive information from another device and/or provide information to another device. In some embodiments, the communication interface may provide for communications with another device via a network, such as a local area network (LAN), a wide area network (WAN), a metropolitan area network (MAN), a private network, an ad hoc network, an intranet, the Internet, a fiber optic-based network, a cellular network (e.g., a fifth generation (5G) network, sixth generation (6G) network, a long-term evolution (LTE) network, a third generation (3G) network, a code division multiple access (CDMA) network, and the like), a public land mobile network (PLMN), a telephone network (e.g., the Public Switched Telephone Network (PSTN)), or the like, and/or a combination of these or other types of networks. Alternatively or additionally, the communication interface may provide for communications with another device via a device-to-device (D2D) communication link, such as FlashLinQ, WiMedia, Bluetooth, ZigBee, Wi-Fi, LTE, 5G, and the like. In other embodiments, the communication interface may include an Ethernet interface, an optical interface, a coaxial interface, an infrared interface, a radio frequency (RF) interface, or the like. It is understood that other embodiments are not limited thereto, and may be implemented in a variety of different architectures (e.g., bare metal architecture, any cloud-based architecture or deployment architecture such as Kubernetes, Docker, OpenStack, etc.).

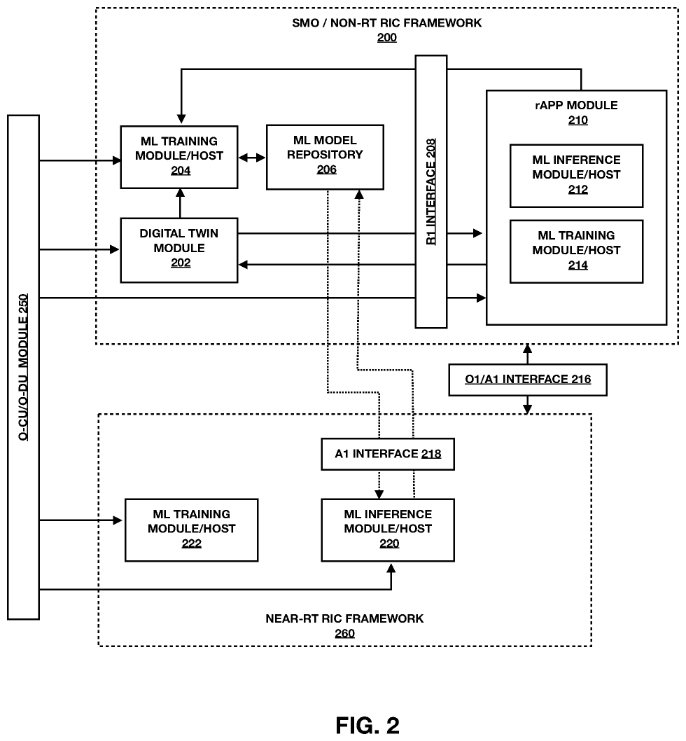

FIG. 2 illustrates a process flow and various modules for the O-RAN modeling and training platform method and system of the disclosure described herein according to one or more exemplary embodiments. In particular, FIG. 2 illustrates a service, management, and orchestration (SMO) and Non-RT RIC architecture and framework 200 of the disclosure described herein that implements a digital twin module 202 (i.e., a simulated/replica model of a physical network), and a Near-RT RIC framework with respect to the physical O-RAN. In part, of the objectives of framework 200 is to improve the ML model training module 204A and testing process in the Non-RT RIC framework. Here, an O-RAN central unit (O-CU) and O-RAN distributed unit (O-DU) (which can be logical nodes) send network data, performance feedback for offline/online training (via O1 interfaces) to an ML training module/host 204, send network data for ML inference (via O1 interfaces) to an rApp module 210, send network data for calibration (via O1 interfaces) with respect to digital twin module 202, send network data for online learning (via E2 interfaces) to ML training module/host 222, and send network data for ML inference to ML inference module/host 220.

Still referring to FIG. 2, ML training module/host 204 can upload and download ML model data from rApp module 210, such as with respect to data from ML inference module/host 212 and ML training module/host 214. In particular, once a model is trained and tested, it can then be deployed within rApp module 210A for additional ML training via module 214 and ML model inference via module 212. Further, ML training module/host 20A can be in bi-directional communication with ML model repository 206 for sending and receiving modeling data. Here, by using data from the digital twin module 202 and the collected physical network data from O-CU/O-DU module 250, the system can be used to train and test the ML model either offline via ML training module/host 204 or online via ML model module 222 within the real physical network.

It is noted that real network data from the O-RAN interfaces can often be limited and not provide suitable training for a model to address a particular scenario or cover all the cases to ensure reliable operation powered by AI/ML technology. In addition, the ML model may need to be tested and proven reliable in all possible scenarios before the real network problem happens. However, as shown in FIG. 2, the digital twin module 202 of the disclosure described herein provided within the Non-RT RIC framework 200 can improve the performances of the training and testing process by performing and generating all possible scenarios offline within the ML training module/host before an ML model is implemented within the real physical network, thereby providing a matured and tested ML model to operate within the real physical network. Here, the digital twin module 202, implemented through computer simulation, can represent a digital replica of a physical O-RAN network as if it is real through advanced simulation and modelling.

Further, rApps and xApps (FIGS. 2-6) can access the digital twin module 202 (and its functionality) in the Non-RT RIC framework and the Near-RT RIC framework via R1 and Near-RT RIC API interfaces respectively, and access AI/ML workflow related services for AI/ML model training and testing. The rApp can directly access the training data generated from the digital twin via the R1 interface for AI/ML model training in the rApp itself, or load the AI/ML models into the training host in the Non-RT RIC framework for platform layer model training and testing and specify via the R1 interface whether and when the physical network data or digital twin data should be used. xApp AI/ML model training that happens in the Non-RT RIC framework, in the training host, and an xAppvendor or operator can specify through some standard interface whether and when the physical or the digital twin module data should be used for training and testing. The xApp AI/ML model training can also happen in the Near-RT RIC framework, in the training host, an xApp can specify through Near-RT RIC API interface whether and when the physical or the digital twin module data should be used for training and testing. xApp can also access the training data generated from the digital twin via the Near-RT RIC API interface for AI/ML model training in the xApp itself.

Still referring to FIG. 2, in one method of operation, the digital twin module 202 may be implemented at a slower time scale relative to real time. For example, in the 3GPP 4G-LTE standard, a frame can have a duration of 10 msec, and when implementing a signal waveform on the digital twin module, its frame duration may last much longer than 10 msec (e.g., 100 msec, or 1 sec, or more, or any number which is not a multiple of 10 msec). In fact, real-time processing may require a large number of computing resources, multiple CPU and multiple threads to be able to generate the LTE waveform in real-time. By contrast, the system and method of the disclosure described herein can be implemented with a limited number of CPU, cores, threads, processes, or any other type of processing units because the real-time constraints can be relaxed and extended.

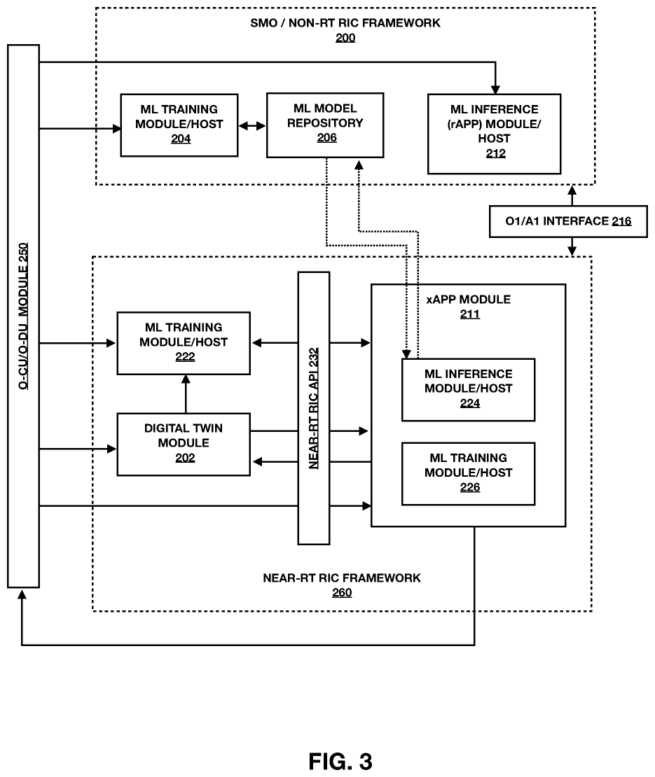

FIG. 3 illustrates an alternative embodiment of FIG. 2, wherein the digital twin module 202 can be implemented in the Near-RT RIC framework 260. In this embodiment, O-CU/O-DU module 250 can send real network data (via an E2 interface) to the ML training module/host 222 for training and testing used by xApp module 210 either offline or online, wherein the xApp module 210 can include an inference module 224 and an ML training module/host 226. The performance of the digital twin module 202 can be calibrated with real data captured from the O-CU/O-DU module 250 (via an E2 interface) in order to ensure the digital twin module is behaving as close to the real network deployment as possible for reliable RIC AI/ML model training and testing. The xApp module 210 can also access the digital twin module 202 in the Near-RT RIC framework 260 via a Near-RT RIC API/SDK interface 232 for AI/ML model training and testing. The xApp module 210 can further directly access the training data generated from the digital twin module 202 via the Near-RT RIC API/SDK 232, or load the AI/ML models (from ML training module/host 222 or ML model repository 206) into the training host in the Near-RT RIC framework for platform layer model training and testing and specify via the Near-RT RIC API/SDK 232 whether and when the physical network data or digital twin module data should be used. Here, the other modules and methodologies as discussed with respect to FIG. 2 are incorporated herein with respect to FIG. 3.

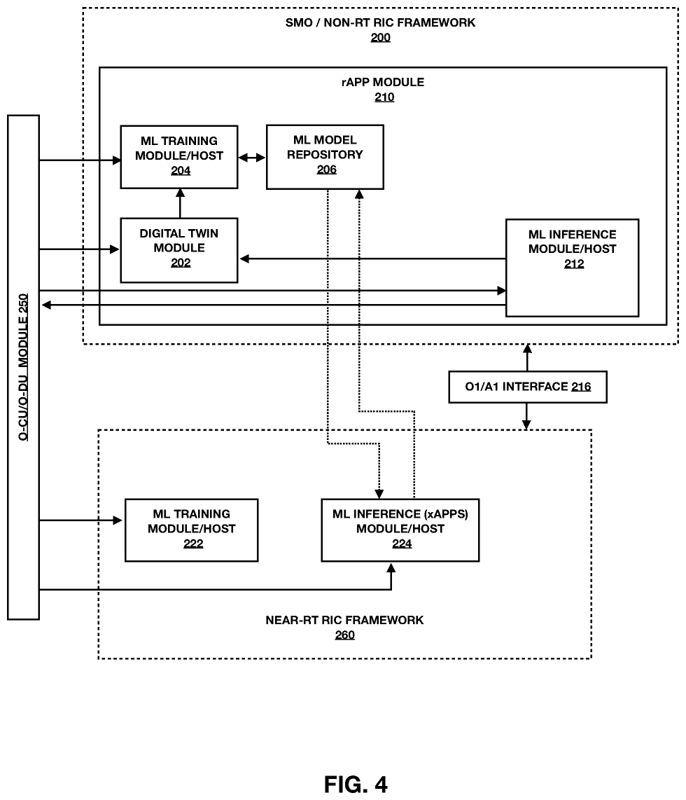

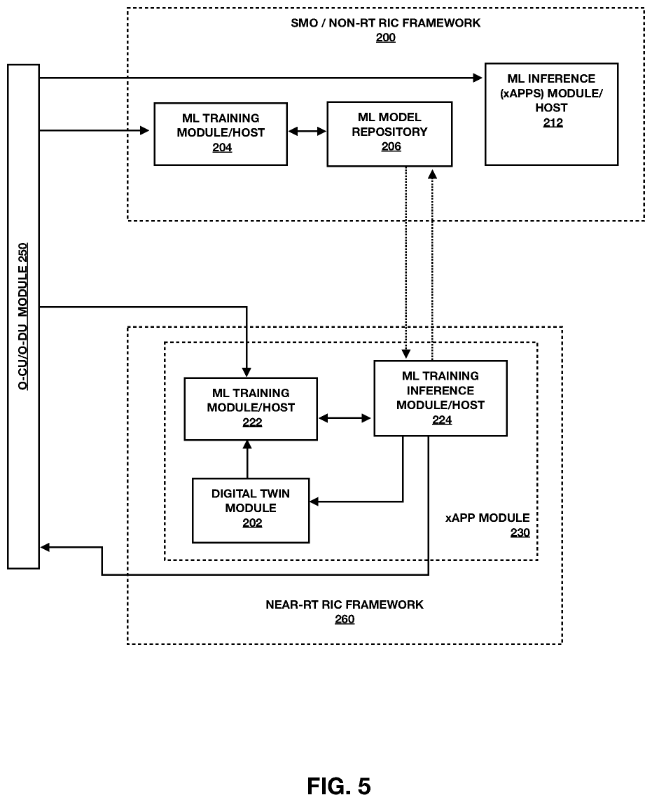

FIGS. 4 and 5 illustrate additional alternative embodiments of FIG. 2, wherein the digital twin module 202 can be implemented within the application layer of the Non-RT RIC 200 via rApp module 210 for AI/ML model training and testing, as shown in FIG. 4, or implemented within the application layer of the Near-RT RIC framework 260 via xApp module 230 for AI/ML model training and testing, as shown in FIG. 5. For either embodiment of FIG. 4 or 5, the AI/ML training and testing tasks are executed in the applications layer rather than the Non-RT or Near-RT RIC framework/platform layer. This can allow xApp or rApp vendors or third parties more flexibility in implementation choices for AI/ML model training rather than relying on the Non-RT RIC or Near-RT RIC framework AI/ML training services provided via standard API interfaces (e.g., R1 interface and Near-RT RIC API). Here, the embodiments of FIGS. 4 and 5 allow xApp and rApp vendors to provide the AI/ML training and testing services based on digital twin module 202 to other vendors and other applications via a standard interface. Here, the other modules and methodologies discussed with respect to FIG. 2-3 are incorporated herein with respect to FIGS. 4 and 5.

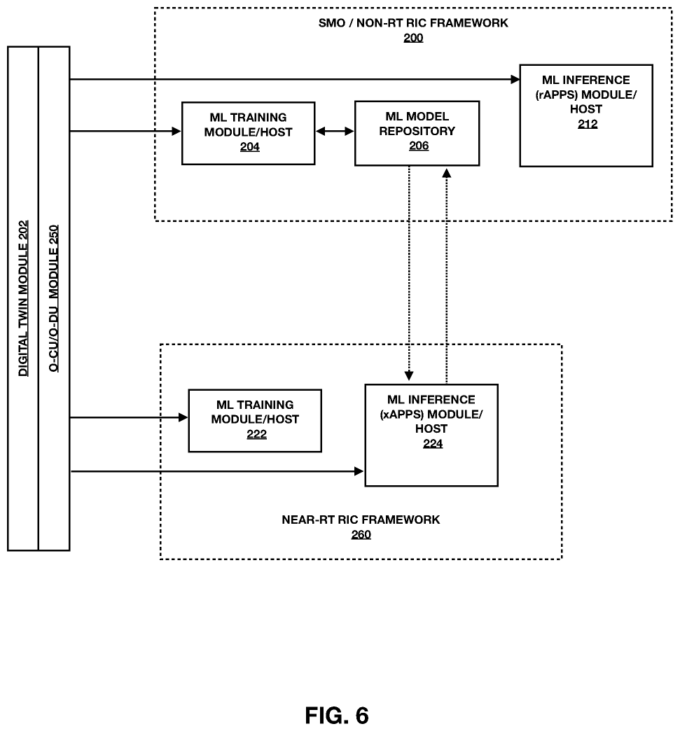

FIG. 6 illustrates another alternative embodiment of FIG. 2, wherein the digital twin module 202 can be implemented outside the Near-RT framework 260 and Non-RT RIC framework 200. In this embodiment, the digital twin module 202 can simulate the real physical network environment and also be running in parallel with the real physical network. From the RIC framework 200 or 260 point of view, there can be no substantial difference between the physical network and the simulated network provided by the digital twin module 202. Here, the RIC frameworks 200 or 260 can communicate with both the digital twin module 202 and the physical network using O-CU/O-DU module 250 (via standard O-RAN interfaces, O1, O2 and E2). Here, the embodiment of FIG. 6 can allow the digital twin module 202 to be provided via third parties or vendors in lieu of the RIC platform vendor. Further, with this embodiment, interoperability matters and performance overhead on the external interfaces (e.g., O1, O2 and E2) may need to be taken into account during online ML training where several training scenarios will be generated. Here, the other modules and methodologies as discussed with respect to FIG. 2-5 are incorporated herein with respect to FIG. 6.

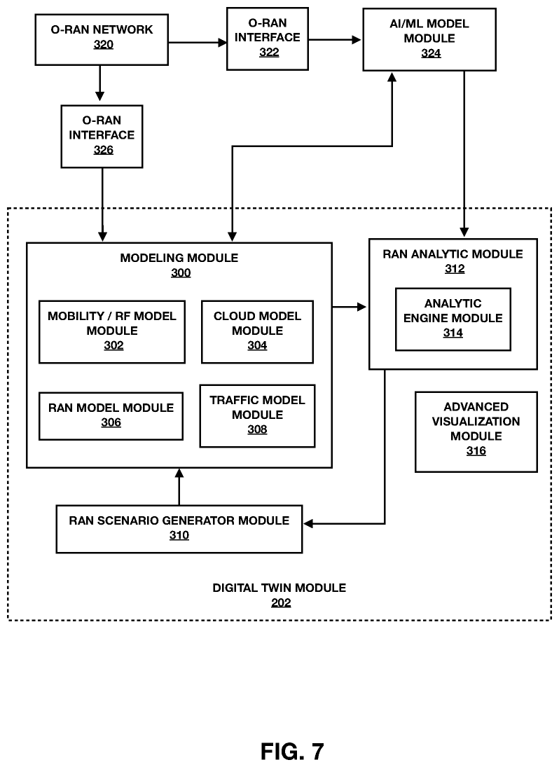

FIG. 7 illustrates a process flow and various modules for the digital twin module 202 of the disclosure described herein, according to some exemplary embodiments. In particular, digital twin module 202 can include a RAN scenario generator module 210 that can create and configure various network related scenarios to a modelling module 300 for modeling and simulation. In particular, module 300 can include a mobility/RF model module 302, cloud model module 304, and a RAN model module 306, and a traffic model module 308. The modelling module can receive data from the O-RAN network 320 via an O-RAN interface 326, and also send and receive data to/from AI/ML model module 324. Further, the AI/ML model module 324 may also receive data from the O-RAN network 320 via an O-RAN interface 322. Further, digital twin module 202 may also include a RAN analytic module 312 that includes an analytic engine module 314 (for performance feedback) that can receive data from modeling module 300 and further send data as input to the RAN scenario generator module 310.

Still referring to FIG. 7, in one exemplary method of operation, RAN scenario generator module 310 (which can be powered with AI/ML technology) can configure the parameters of the digital twin model, or the simulated O-RAN network, in order to automatically generate one or a plurality of test scenarios or network events (data sets) to challenge the RIC AI/ML model module 324 under training and testing. The RAN scenario generator module 310 can also be trained and further evolve based on the performance feedback from the RAN analytic module 312 forming a Generative Adversarial Network (GAN). The evolving process of the digital twin module 202 can continuously run in a loop and provide challenging network scenarios (such as down/inoperable nodes, network coverage issues, etc.) with the RIC AI/ML models under training and testing. In example embodiments, the training and testing scenarios generated by the RAN scenario generator module 310 can automatically become more and more challenging as the performance of the RIC AI/ML model module 324 improves, until a certain level of intelligence and reliability is achieved. The foregoing methods can be applied to all stages of the AI/ML training and testing process in the RIC, such as offline before the AI/ML model is deployed for operation, online after the AI/ML model is deployed but before a control action and guidance from the AI/ML model has been given to the network, and online after the AI/ML model is deployed and after a control action and guidance has been given by the AI/ML model.

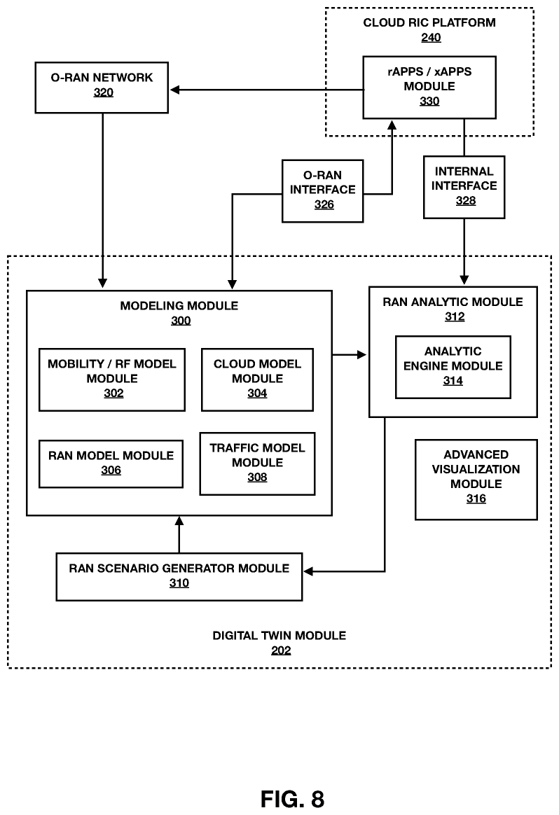

FIG. 8 illustrates an alternative embodiment of FIG. 7. In particular, digital twin module 202 may also be accessed and operated in the cloud (or via application servers) via one or more third parties or vendors. In particular, O-RAN network 320 may send network data to modeling module 300, wherein the O-RAN network 320 may also receive information from rApps/xApps module 330. In addition, rApps/xApps module 330 may also send and receive information via the O-RAN interface 326 to and from modeling module 300. Further, rApps/xApps module 300 may also send information to the RAN analytic module 312 via an internal interface 328. In one exemplary method of operation, O1, O2 and E2 interfaces can be used to collect real network data from the O-RAN network for training and testing the AI/ML models used by the rApps/xApps module 330 either offline or online. The performance of the digital twin module 202 can be calibrated with the real data captured from the network either through standard O1, O2 and E2 interfaces or proprietary interfaces in order to make sure the digital twin module 202 is behaving as close to the real network deployment as possible for reliable Cloud RIC platform 240 and its AI/ML model training and testing. The digital twin module 202 can provide generative training data and interact with the AI/ML models in the Cloud RIC platform 240 through either standard O1, O2 and E2 interfaces (O-RAN interfaces 326) or proprietary interfaces. It is also possible to deploy the digital twin module 202 inside the Cloud RIC platform 240 or application layer. Here, the other modules and methodologies as discussed with respect to FIG. 7 are incorporated herein with respect to FIG. 8.

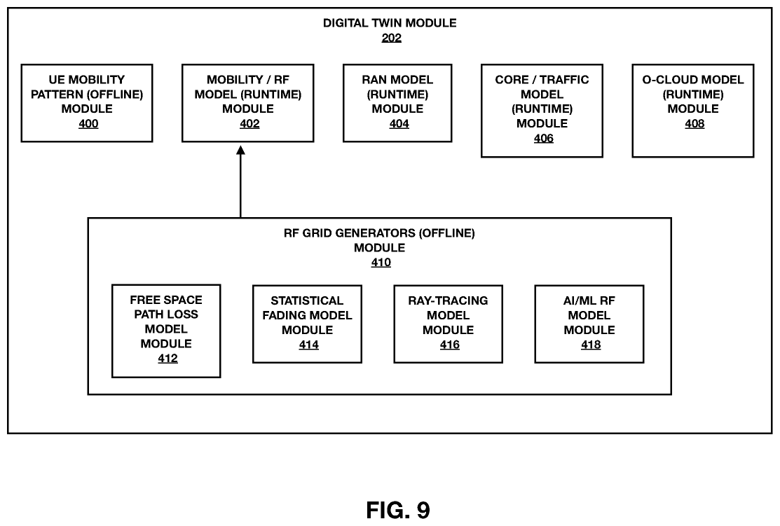

Referring to FIG. 9, the digital twin module 202 system can include either one or a plurality of units or modules. In some example embodiments, there can be two different types of units: 1) “offline” units or modules implemented at slower timescales relative to real-time execution of the system; 2) “runtime” units or modules implemented at the same or faster timescale relative to real-time execution of the system. In one exemplary embodiment, the offline units or modules can include but are not limited to the RF grid generator module 410 and the user device/equipment (UE) mobility pattern generator module 402. Specifically, RF grid generator module 410 may include a free space path loss model module 412, statistical fading model module 414, ray-tracing model module 416, and an AI/ML RF model module 418. The model can be flexibly selected based on modeling accuracy requirements for training a particular type of AI/ML model for a particular use case. In another exemplary embodiment, the runtime units or modules can include but not be limited to the mobility/RF model runtime module 402, RAN model module 404, core/traffic model module 406, and O-Cloud model module 408. However, it is contemplated within the scope of the present disclosure described herein that any unit that may belong to the digital twin module 202 system may be either an offline unit or runtime unit.

As illustrated in FIG. 9, the RF grid propagation generator module 410 and user equipment (UE) mobility pattern behaviors module 400 can be simulated by the mobility/RF Model module leveraging advanced ray tracing or AI/ML from ray-tracking model module 416 based RF modelling technology from RF model module 418 for realistically replicating the RF environment. The network protocol stack functions (i.e., physical layer, L2 and L3) are simulated with the RAN model leveraging existing RAN function implementation and simulation techniques. The higher layer applications traffic patterns and core behaviors are simulated by the traffic model, or module 406. The cloud infrastructure of the O-RAN network is simulated with the O-Cloud model, or module 408. Here, the performance of the digital twin module 202 (i.e., the simulated O-RAN network) can be calibrated with real data captured from the open network interfaces, O1, O2 and A1 or any proprietary interface, in order to ensure the digital twin module 202 is behaving as close as possible to the real network deployment reliable RIC AI/ML model training and testing.

Still referring to FIG. 9, the runtime units can directly interact with RIC AI/ML units during training and testing at relatively fast speeds for large interactive training and data set generation. The behaviors of the digital twin module models can be the same as the real network for realistic replications, and as such, may encounter the same computational complexity (e.g., full L1, L2 and L3 stack implementation). However, in order for the digital twin modules to be lightweight, the clock speed for driving the models can be much slower than the network real-time requirement for training and testing purposes by relaxing its constraints relative to real-time constraints (such as with respect to timescale). It is contemplated within the scope of the present disclosure described herein that soft real-time or faster than real-time for massive training data set generation is also possible with smaller amount of CPU and memory resource if the hard real-time timing constraint is removed.

Still referring to FIG. 9, it is contemplated within the scope of the present disclosure described herein that some behaviors of the real physical network can be abstracted with simplification to further reduce the computational cost of the digital twin module 202 models. For example, RF environment techniques, such as ray-tracing (via module 416) or AI/ML based RF models (via module 418), may involve high computational complexity. Such modelling computations can be moved offline. As shown in FIG. 9, the offline RF grid generator module 410 derives the RF signal power and interference strength in the real-world environment based on ray-tracing and AI/ML technologies using limited CPU resources and at much slower speeds than their runtime counterpart. This offline process is acceptable since RF large scale environments do not change as frequently as the rest of the network which interact with the RIC AI/ML models. The large RF environment is typically changed when antenna and beam configurations are changed (e.g., antenna down tilt, azimuth, gain and beam pattern, etc.) which happens at relatively slow speed. Further, UE mobility pattern computation (via module 400) can also be performed at slow speed which can generate UE movement trajectories offline for the runtime layer to read and replay. Furthermore, the computation of RF grid and UE mobility pattern can be done with GPU or FGPA acceleration which can greatly improve the speed with large parallelism and without hard latency or real-time requirements in the training and testing environment. In some AI/ML training and testing scenarios where RF environment details are not needed, the RF model can be also simplified with statistics-based RF modelling techniques (via module 414) or free space path loss models (via module 412) in the simplest form to minimize the complexity.

It is understood that the specific order or hierarchy of blocks in the processes/flowcharts disclosed herein is an illustration of example approaches. Based upon design preferences, it is understood that the specific order or hierarchy of blocks in the processes/flowcharts may be rearranged. Further, some blocks may be combined or omitted. The accompanying method claims present elements of the various blocks in a sample order, and are not meant to be limited to the specific order or hierarchy presented.

Some embodiments may relate to a system, a method, and/or a computer readable medium at any possible technical detail level of integration. Further, one or more of the above components described above may be implemented as instructions stored on a computer readable medium and executable by at least one processor (and/or may include at least one processor). The computer readable medium may include a computer-readable non-transitory storage medium (or media) having computer readable program instructions thereon for causing a processor to carry out operations.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program code/instructions for carrying out operations may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects or operations.

These computer readable program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer readable media according to various embodiments. In this regard, each block in the flowchart or block diagrams may represent a module, microservice(s), segment, or portion of instructions, which comprises one or more executable instructions for implementing the specified logical function(s). The method, computer system, and computer readable medium may include additional blocks, fewer blocks, different blocks, or differently arranged blocks than those depicted in the Figures. In some alternative implementations, the functions noted in the blocks may occur out of the order noted in the Figures. For example, two blocks shown in succession may, in fact, be executed concurrently or substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

It will be apparent that systems and/or methods, described herein, may be implemented in different forms of hardware, firmware, or a combination of hardware and software. The actual specialized control hardware or software code used to implement these systems and/or methods is not limiting of the implementations. Thus, the operation and behavior of the systems and/or methods were described herein without reference to specific software code—it being understood that software and hardware may be designed to implement the systems and/or methods based on the description herein.

What is claimed is:

1. A method of creating a lightweight and realistic digital replica of a network for machine learning and training, the method comprising:
generating a digital twin of a network, wherein the digital twin is calibrated based on receiving performance metrics data from the network;
training a machine learning model based on data generated from the digital twin; and
operating the trained machine learning model within the network.

2. The method of claim 1, wherein the network is based on an open radio access network (O-RAN).

3. The method of claim 2, further comprising:
operating the digital twin within a non-real-time (Non-RT) radio access network intelligent controller (RIC) framework as part of an artificial intelligence (AI) or machine learning (ML) workflow for AI or ML model training and testing.

4. The method of claim 2, further comprising:
operating the digital twin within a near-real-time (Near-RT) radio access network intelligent controller (RIC) framework as part of an artificial intelligence (AI) or machine learning (ML) workflow for AI or ML model training and testing.

5. The method of claim 2, further comprising:
operating the digital twin in parallel with the O-RAN, wherein the digital twin is further operated outside of a non-real-time (Non-RT) radio access network intelligent controller (RIC) framework and a near-real-time (Near-RT) radio access network intelligent controller (RIC) framework.

6. The method 1, wherein the step of generating a digital twin of the network further comprises:
analyzing a performance of the machine learning model; and
generating one or more network scenarios via radio access network (RAN) scenario generator based on the performance of the machine learning model.

7. The method of claim 6, further comprising:
modeling the network based on the received network data from the network and the generated one or more network scenarios from the RAN scenario generator.

8. The method of claim 7, further comprising:
monitoring a performance of the modeled network;
providing feedback to the RAN scenario generator based on the monitored performance of the modeled network; and
optimizing the modeled network based on the provided feedback to the RAN scenario generator.

9. The method of claim 8, wherein the digital twin comprises an offline simulation module and a runtime simulation module.

10. The method of claim 9, further comprising:
generating user equipment (UE) mobility pattern within the offline simulation module;
simulating radio frequency (RF) propagation within the offline simulation module, and generating an RF map at least partially representing power and interference at each location within a geographical area; and
loading the UE mobility pattern and RF map generated to generate training or testing data to an artificial intelligence (AI) or machine learning (ML) model under training or testing in run time.

11. An apparatus for creating a lightweight and realistic digital replica of a network for machine learning and training, comprising:
a memory storage storing computer-executable instructions; and
a processor communicatively coupled to the memory storage, wherein the processor is configured to execute the computer-executable instructions and cause the apparatus to:
generate a digital twin of a network, wherein the digital twin is calibrated based on receiving performance metrics data from the network;
train a machine learning model based on data generated from the digital twin; and
operate the trained machine learning model within the network.

12. The apparatus of claim 11, wherein the network is based on an open radio access network (O-RAN).

13. The apparatus of claim 12, wherein the computer-executable instructions, when executed by the processor, further cause the apparatus to:
operate the digital twin within a non-real-time (Non-RT) radio access network intelligent controller (RIC) framework as part of an artificial intelligence (AI) or machine learning (ML) workflow for AI or ML model training and testing.

14. The apparatus of claim 12, wherein the computer-executable instructions, when executed by the processor, further cause the apparatus to:
operate the digital twin within a near-real-time (Near-RT) radio access network intelligent controller (RIC) framework as part of an artificial intelligence (AI) or machine learning (ML) workflow for AI or ML model training and testing.

15. The apparatus of claim 12, wherein the computer-executable instructions, when executed by the processor, further cause the apparatus to:
operate the digital twin in parallel with the O-RAN, wherein the digital twin is further operated outside of a non-real-time (Non-RT) radio access network intelligent controller (RIC) framework and a near-real-time (Near-RT) radio access network intelligent controller (RIC) framework.

16. The apparatus of claim 11 1, wherein the step of generating a digital twin of the network and wherein the computer-executable instructions, when executed by the processor, further cause the apparatus to:
analyze a performance of the machine learning model; and
generate one or more network scenarios via radio access network (RAN) scenario generator based on the performance of the machine learning model.

17. The apparatus of claim 16, wherein the computer-executable instructions, when executed by the processor, further cause the apparatus to:
model the network based on the received network data from the network and the generated one or more network scenarios from the RAN scenario generator.

18. The apparatus of claim 17, wherein the computer-executable instructions, when executed by the processor, further cause the apparatus to:
monitor a performance of the modeled network;
provide feedback to the RAN scenario generator based on the monitored performance of the modeled network; and
optimize the modeled network based on the provided feedback to the RAN scenario generator;

19. The apparatus of claim 18, wherein the digital twin comprises an offline simulation module and a runtime simulation module.

20. A non-transitory computer-readable medium comprising computer-executable instructions for creating a lightweight and realistic digital replica of a a network for machine learning and training by an apparatus, wherein the computer-executable instructions, when executed by at least one processor of the apparatus, cause the apparatus to:
generate a digital twin of a network, wherein the digital twin is calibrated based on receiving performance metrics data from the network;
train a machine learning model based on data generated from the digital twin; and
operate the trained machine learning model within the network.
